(19) United States
(12) Patent Application Publication
(10) Pub. No.: US 2017/0338792 A1
(43) Pub. Date: Nov. 23, 2017

(54) COMMON MODE FILTER AND METHOD OF MANUFACTURING THE SAME

(71) Applicant: SAMSUNG ELECTRO-MECHANICS CO., LTD., Suwon-si (KR)

(72) Inventors: Kwang Jik LEE, Suwon-si (KR); Ju Hwan YANG, Suwon-si (KR); Jung Wook SEO, Suwon-si (KR)

(21) Appl. No.: 15/409,933

(22) Filed: Jan. 19, 2017

(30) Foreign Application Priority Data
May 19, 2016 (KR) 10-2016-0061195

(51) Int. Cl. H03H 7/42; H01F 3/08; H01F 17/04

(52) U.S. Cl. CPC H03H 7/427; H01F 17/04; H01F 3/08; H01F 2017/048

(57) ABSTRACT

A common mode filter includes: a body disposed on a substrate, wherein the body includes: a coil part including one or more coils and a through-hole formed in a central portion thereof; and a core part including a magnetic powder, disposed on the coil part, and filling the through-hole. A content of the magnetic powder in the core part has a gradient in a stacking direction. Impedance characteristics may be improved by reducing unfilled defect in the core part and securing permeability thereof at the same time.

### CROSS-REFERENCE TO RELATED APPLICATION(S)

This application claims benefit of priority to Korean Patent Application No. 10-2016-0061195 filed on May 19, 2016 in the Korean Intellectual Property Office, the disclosure of which is incorporated herein by reference in its entirety.

### TECHNICAL FIELD

The present disclosure relates to a common mode filter and a method of manufacturing the same.

### BACKGROUND

Examples of causes of abnormal voltages and high frequency noise include a switching voltage generated in a circuit, power supply noise included in a power supply voltage, an unnecessary electromagnetic signal, electromagnetic noise, and the like. In order to prevent the above-mentioned abnormal voltage and high frequency noise from being introduced into the circuit, a common mode filter (CMF) is commonly used.

Such a common mode filter commonly uses a magnetic sheet as an encapsulation material. The magnetic sheet may implement high inductance, forming a magnetic path within the common mode filter. Impedance indicating capacity of the common mode filter is related to the permeability of ferrite, a number of coil turns, a structure of the common mode filter, and the like.

Thus, a method capable of improving impedance characteristics of the common mode filter is required.

### SUMMARY

An exemplary embodiment in the present disclosure may provide a common mode filter having improved impedance characteristics by reducing unfilled defects in a core part and securing permeability of the core part at the same time, and a method of manufacturing the same.

According to an exemplary embodiment in the present disclosure, a common mode filter may include: a body disposed on a substrate, wherein the body includes: a coil part including one or more coils and a through-hole formed in a central portion thereof; and a core part including a magnetic powder, disposed on the coil part, and filling the through-hole A content of the magnetic powder in the core part has a gradient in a stacking direction.

According to an exemplary embodiment in the present disclosure, a method of manufacturing a common mode filter may include: forming a coil sheet including one or more coils on a substrate; forming a through-hole in a central portion of the coil sheet; and forming a body having a filled through-hole by stacking and compressing a first magnetic sheet, a second magnetic sheet, and a third magnetic sheet on the coil sheet. The first to third magnetic sheets have different contents of magnetic powder.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 illustrates a schematic perspective view of a common mode filter according to an exemplary embodiment in the present disclosure;

FIG. 2 illustrates a cross-sectional view taken along line I-I′ of FIG. 1;

FIG. 3 illustrates a schematic enlarged view of an example of part A of FIG. 2; and

FIG. 4 illustrates a schematic process cross-sectional view illustrating a process of forming a common mode filter according to an exemplary embodiment in the present disclosure.

### DETAILED DESCRIPTION

Hereinafter, exemplary embodiments of the present disclosure will be described in detail with reference to the accompanying drawings.

Hereinafter, a common mode filter according to the present disclosure will be described.

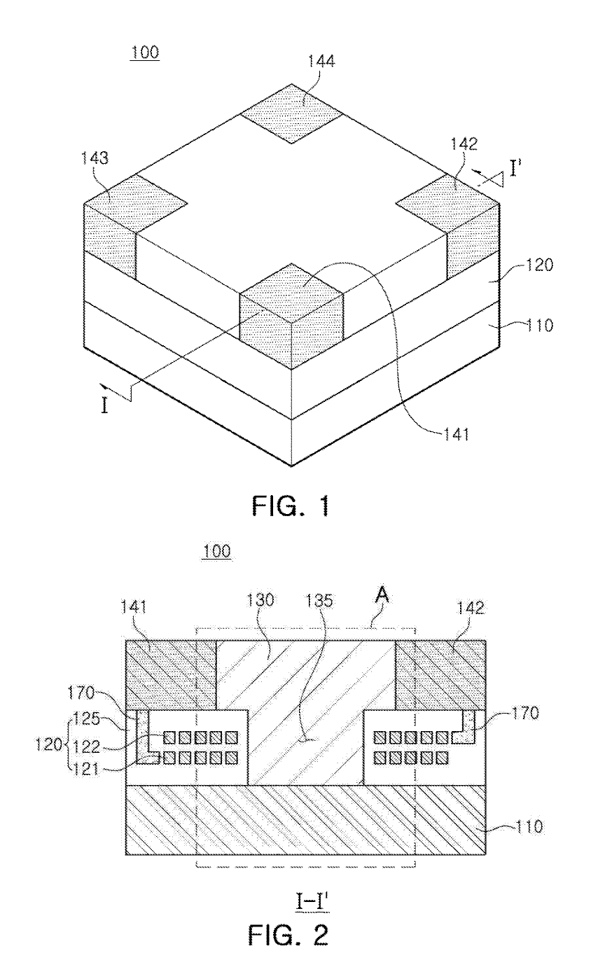

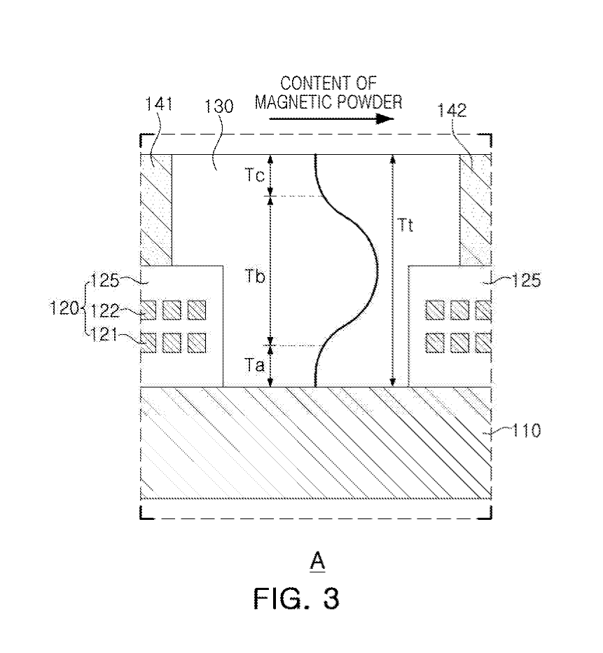

FIG. 1 illustrates a schematic perspective view of a common mode filter according to an exemplary embodiment in the present disclosure, FIG. 2 illustrates a cross-sectional view taken along line I-I′ of FIG. 1, and FIG. 3 illustrates a schematic enlarged view of an example of part A of FIG. 2.

Referring to FIGS. 1 through 3, a common mode filter 100 according to an exemplary embodiment in the present disclosure may include a body 120 and 130 disposed on a substrate 110. The body 120 and 130 includes a coil part 120 including one or more coils 121 and 122 and a through-hole 135 formed in a central portion thereof, and a core part 130 including a magnetic powder, disposed on the coil part 120, and formed by filling the through-hole 135, and the core part 130 has a content gradient of the magnetic powder in a stacking direction.

A configuration of the common mode filter 100 will be described with reference to FIG. 1. The common mode filter 100 may include a substrate 110, a coil part 120 disposed on the substrate and including coils therein, and external electrodes 141, 142, 143, and 144 electrically connected to the coils.

The substrate 110 may be positioned below the body.

The substrate 110 may include a magnetic material, and may be, for example, a ferrite substrate. In the case in which the substrate 110 is the ferrite substrate, the substrate 110 may be the ferrite substrate having permeability of 300 or more.

The body 120 and 130 may be disposed on the substrate 110, and may include the coil part 120 and the core part 130.

The coil part 120 may be formed by forming a plurality of coils in the ferrite substrate 125 and covering the coils with an insulating layer (not shown).

The coil part 120 may include one or more coils, and may include first and second coils 121 and 122 as illustrated, but is not limited thereto.

The first and second coils 121 and 122 may be disposed in a spiral form, and may be formed of a metal having excellent electrical conductivity, for example, silver (Ag), palladium (Pd), aluminum (Al), nickel (Ni), titanium (Ti), gold (Au), copper (Cu), platinum (Pt), or an alloy thereof.

The insulating layer may be formed in a stacked form using a build-up film such as Ajinomoto build-up films (ABF), polyimide, an epoxy, benzocyclobutene (BCB), or the like.

One end portions of the coils 121 and 122 may be exposed to a top surface of the body through a connection electrode 170, and the first and second coils 121 and 122 may be electrically connected to the first and second external electrodes 141 and 142 through the connection electrode 170, respectively.

The coil part 120 may include the through-hole 135 formed in the central portion thereof. The through-hole 135 may be formed by a laser punching or mechanical punching method.

The core part 130 may be disposed on the coil part 120 and may be formed by filling the through-hole 135.

The core part 130 may be a magnetic resin composite including the magnetic powder, and the magnetic powder may be powder having magnetic characteristics, for example, ferrite powder, but is not limited thereto.

The magnetic resin composite means a composite manufactured by dispersing a magnetic material in a polymer resin, and as the magnetic material, the magnetic material such as ferrite, pure iron, or the like may be used.

In the case in which the core part includes the magnetic resin composite, permeability of the core part may be adjusted depending on a content of the magnetic material included in the magnetic resin composite.

By forming the core part including the magnetic powder in the through-hole, closed magnetic paths may be formed around the coils to acquire high impedance.

In order to acquire high impedance in the core part, an improved effect may be obtained as permeability of the magnetic resin composite filled in the through-hole is increased, and in order to increase permeability of the magnetic resin composite, the content of the magnetic powder included in the magnetic resin composite needs to be high.

In a case in which the through-hole is filled with the magnetic resin composite having the high content of the magnetic powder, an unfilled defect may occur in the through-hole, in which an air layer exists in the through-hole.

In a case in which the air layer exists in the body, a defect may occur in a high temperature and reliability test of the common mode filter, and may not acquire the above-mentioned effect of impedance.

Referring to FIG. 3, the common mode filter 100 according to an exemplary embodiment may satisfy that the core part 130 has the content gradient of the magnetic powder in the stacking direction.

That is, the common mode filter according to the present disclosure may control fluidity and adhesion of the magnetic resin composite to fill the core part with the magnetic resin composite, to thereby prevent an occurrence of the unfilled defect when the magnetic resin composite is filled in the through-hole. In addition, by improving permeability of the core part, high impedance may be obtained.

In case in which the core part 130 is divided into a first region, a second region, and a third region from a bottom surface of the core part, that is, the substrate 110 exposed to the through-hole, the first region may correspond to a lower portion of the core part, the second region may correspond to a center portion of the core part, and the third region may correspond to an upper portion of the core part 130.

The content of the magnetic powder in the second region may be greater than the contents of the magnetic powder in the first and third regions. By increasing the content of the magnetic powder in the second region, permeability of the core part may be secured.

The content of the magnetic powder in the first region may be smaller than the contents of the magnetic powder in the second and third regions. Since the first region has a resin content higher than the second and third regions, the first region may have high fluidity and adhesion to thereby prevent the unfilled defect of the core part.

The content of the magnetic powder in the third region may correspond to the content of the magnetic powder according to the related art. The third region is disposed at an upper portion of the core part, whereby surface and exterior characteristics of the common mode filter may be secured.

A thickness Tb of the second region in an overall thickness Tt of the core part 130 may be greater than a thickness Ta of the first region and a thickness Tc of the third region.

A permeability decrease of the first and third regions is compromised by forming the second region having high permeability to be thick, whereby permeability of the core part may be improved and impedance characteristics of the common mode filter may be improved.

In addition, the first region having high fluidity is disposed, whereby the unfilled defect of the core part may be prevented, by which high temperature and reliability characteristics of the common mode filter may be secured.

A thickness ratio of the first region, the second region, and the third region may be 2:7:1, but is not limited thereto. The above-mentioned thickness ratio may be suitable for a range in which it is satisfied that the thickness of the second region is greater than the thicknesses of the first and third regions, and permeability of the core part is secured.

Hereinafter, a method of manufacturing a common mode filter according to the present disclosure will be described.

A method of manufacturing a common mode filter according to an exemplary embodiment of the present disclosure may include an operation of forming a coil sheet including one or more coils on a substrate, an operation of forming a through-hole in a central portion of the coil sheet, and an operation of forming a body having a filled through-hole by sequentially stacking and compressing first to third magnetic sheets on the coil sheet. The first to third magnetic sheets have different contents of magnetic powder.

First, a coil sheet including one or more coils may be formed on a substrate.

The substrate may include a magnetic material, and may be, for example, a ferrite substrate. In the case in which the substrate is the ferrite substrate, the substrate may be the ferrite substrate having a permeability of 300 or more.

The coil sheet may include one or more coils.

The coil sheet formed on the substrate may be formed by forming the coils on the ferrite substrate and then forming an insulating layer so as to surround surfaces of the coils.

Next, a through-hole may be formed in a central portion of the coil sheet.

The through-hole may be formed to penetrate through the central portion of the coil sheet, and may be formed by a laser punching or mechanical punching method.

Next, external electrodes may be formed on the coil sheet.

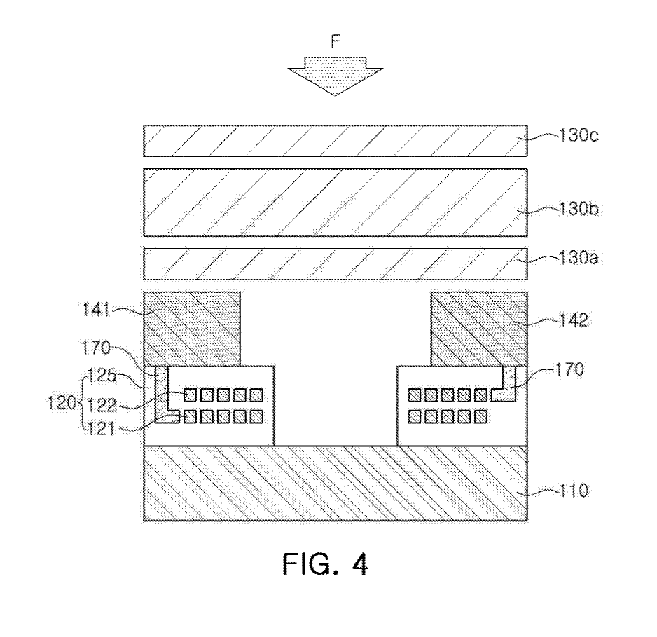

FIG. 4 illustrates a schematic process cross-sectional view illustrating a process of forming a common mode filter according to an exemplary embodiment in the present disclosure.

Referring to FIG. 4, the body having the filled through-hole may be formed by sequentially stacking and compressing first to third magnetic sheets 130a, 130b, and 130c on the coil sheet 120. The first to third magnetic sheets 130a, 130b, and 130c are used as an example; the present disclosure, however, is not limited thereto. In a case in which more than three magnetic sheets are used to form the body, the content of the magnetic powder may first increase and then decrease from a lowermost magnetic sheet to an uppermost magnetic sheet, while the fluidity first may decrease and then increase from the lowermost magnetic sheet to the uppermost magnetic sheet.

A magnetic body 50 may be formed by compressing and curing the stacked magnetic sheets 130a, 130b, and 130c by a laminating method or a hydrostatic pressing method after stacking the magnetic sheets 130a, 130b, and 130c.

The first to third magnetic sheets 130a, 130b, and 130c may be manufactured in a sheet type by manufacturing a slurry by mixing a magnetic material, for example, magnetic powder with an organic material such as a polymer resin, applying the slurry onto a carrier film by a doctor blade method, and then drying the applied slurry.

The magnetic powder may be powder having magnetic property, for example, ferrite powder, but is not limited thereto.

The polymer resin may be a thermosetting resin such as an epoxy resin or polyimide.

As the content of the magnetic powder is increased, fluidity of the magnetic sheet may be decreased, but permeability thereof may be increased. In the method of manufacturing a common mode filter according to the present disclosure, the contents and the thicknesses of the magnetic powder of the first to third magnetic sheets are adjusted to thereby secure permeability of the entirety of magnetic sheets and to increase fluidity thereof at the same time, whereby an unfilled defect of the through-hole may be prevented.

The content of the magnetic power of the second magnetic sheet 130b may be greater than the contents of the magnetic powder of the first and third magnetic sheets 130a and 130c.

Since the content of the magnetic powder of the second magnetic sheet is high, permeability of the second magnetic sheet may be higher than permeability of the first and third magnetic sheets.

The second magnetic sheet is to secure permeability of the entirety of magnetic sheets, and impedance characteristics of the common mode filter may be improved by increasing permeability of the second magnetic sheet.

The content of the magnetic powder of the third magnetic sheet 130c may correspond to the content of the magnetic powder according to the related art. The third region is disposed in an upper portion of the core part, whereby surface and exterior characteristics of the common mode filter may be secured.

The content of the magnetic powder of the first magnetic sheet 130a may be smaller than the contents of the magnetic powder of the second and third magnetic sheets 130b and 130c. Since the first magnetic sheet may have permeability lower than the second and third magnetic sheets, but have a high content of a polymer resin having high fluidity, the first magnetic sheet may have fluidity higher than the second and third magnetic sheets.

The first magnetic sheet is to secure fluidity of the entirety of magnetic sheets at the time of compressing the magnetic sheets, and the unfilled defect of the through-hole may be prevented by increasing fluidity of the first magnetic sheet, whereby high temperature and reliability characteristics of the common mode filter may be secured.

When comparing relative permeability of the first to third magnetic sheets, it may be represented as the second magnetic sheet>the third magnetic sheet≧the first magnetic sheet, when comparing fluidity of the first to third magnetic sheets, fluidity of the first to third magnetic sheets may be represented as the first magnetic sheet≧the third magnetic sheet>the second magnetic sheet, and when comparing the thicknesses of the first to third magnetic sheets, the thicknesses of the first to third magnetic sheets may be represented as the second magnetic sheet>the first magnetic sheet>the third magnetic sheet.

Except for the above-mentioned description, a description of characteristics overlapped with those of the common mode filter according to an exemplary embodiment described above will be omitted.

As set forth above, according to the exemplary embodiments in the present disclosure, impedance characteristics may be improved by reducing unfilled defect in the core part and securing permeability of the core part at the same time.

While exemplary embodiments have been shown and described above, it will be apparent to those skilled in the art that modifications and variations could be made without departing from the scope of the present invention as defined by the appended claims.

What is claimed is:

1. A common mode filter comprising:
a body disposed on a substrate,
wherein the body includes:
a coil part including one or more coils and a through-hole formed in a central portion thereof; and
a core part including a magnetic powder, disposed on the coil part, and filling the through-hole, a content of the magnetic powder in the core part has a gradient in a stacking direction.

2. The common mode filter of claim 1, wherein the core part has a first region, a second region, and a third region sequentially stacked on one another,
a content of the magnetic powder in the second region is greater than contents of the magnetic powder in the first and third regions.

3. The common mode filter of claim 2, wherein the content of the magnetic powder in the first region is smaller than the contents of the magnetic powder in the second and third regions.

4. The common mode filter of claim 2, wherein in an overall thickness of the core part,
a thickness of the second region is greater than thicknesses of the first and third regions.

5. A method of manufacturing a common mode filter, the method comprising:
forming a coil sheet including one or more coils on a substrate;
forming a through-hole in a central portion of the coil sheet; and
forming a body having a filled through-hole by stacking and compressing a first magnetic sheet, a second magnetic sheet, and a third magnetic sheet on the coil sheet,
wherein the first to third magnetic sheets have different contents of magnetic powder.

6. The method of claim 5, wherein a content of the magnetic powder of the second magnetic sheet is greater than contents of the magnetic powder of the first and third magnetic sheets.

7. The method of claim 5, wherein a content of the magnetic powder of the first magnetic sheet is smaller than contents of the magnetic powder in the second and third magnetic sheets.

8. The method of claim 5, wherein a thickness of the second magnetic sheet is greater than thicknesses of the first and third magnetic sheets.

9. The method of claim 8, wherein the thickness of the first magnetic sheet is lower than the thickness of the third magnetic sheet.

10. The method of claim 5, wherein fluidity of the first magnetic sheet is greater than fluidity of the second and third magnetic sheets.
